(19) United States
(12) Patent Application Publication
(10) Pub. No.: US 2026/0362808 A1
(43) Pub. Date: Nov. 12, 2026

(54) DISPLAY PANEL AND DISPLAY DEVICE

(71) Applicant: SHANGHAI TIANMA MICROELECTRONICS CO., LTD., Shanghai (CN)

(72) Inventors: Linzhi WANG, Shanghai (CN); Kerui XI, Shanghai (CN); Baiquan LIN, Shanghai (CN); Yifan XING, Shanghai (CN); Feng QIN, Shanghai (CN)

(73) Assignee: SHANGHAI TIANMA MICROELECTRONICS CO., LTD., Shanghai (CN)

(21) Appl. No.: 19/724,951

(22) Filed: Jun. 30, 2026

(30) Foreign Application Priority Data
Jan. 20, 2026 (CN) 202610078432.7

(51) Int. Cl. H10D 86/40

(52) U.S. Cl. CPC H10D 86/441

(57) ABSTRACT

A display panel and a display device, relating to the field of display technology. The display panel includes multiple signal lines and multiple first-type transmission lines. The signal lines extend along a first direction and are arranged along a second direction. The first-type transmission lines are electrically connected to connection points on the signal lines. The first-type transmission lines are configured to transmit a display signal. At least one of the signal lines includes at least two of the connection points. At least two connection points are provided on the signal line and the at least two connection points are electrically connected to the first-type transmission line, increasing the signal transmission channels from the first-type transmission line to the signal line, that is, reducing the impedance on the transmission path of the display signal.

This application claims the priority to Chinese Patent Application No. 202610078432.7, titled “DISPLAY PANEL AND DISPLAY DEVICE”, filed on Jan. 20, 2026 with the China National Intellectual Property Administration, which is incorporated herein by reference in its entirety.

### FIELD

The present disclosure relates to the field of display, and in particular, to a display panel and a display device.

### BACKGROUND

With the development of display technology, the requirements for display quality have gradually increased. Currently, narrow bezel or even bezel-less design is a development trend in the conventional display technology field. To achieve a narrow bezel or bezel-less design for a display device, related wiring lines are generally arranged within an active area of the display device. The wiring lines include multiple signal lines and multiple transmission lines. One signal line is electrically connected to multiple pixels, and one signal line is electrically connected to one transmission line. The transmission line is configured to transmit a display signal to the signal line, and then the display signal is transmitted to the multiple pixels electrically connected to the signal line via the signal line. Since multiple pixels are electrically connected to the signal line at different positions, delays for different pixels receiving the display signal are inconsistent, affecting a display effect of the display device.

### SUMMARY

In view of this, a display panel and a display device are provided according to the present disclosure.

A display panel is provided, and the display panel includes:
multiple signal lines, where the multiple signal lines extend along a first direction and are arranged along a second direction; and
multiple first-type transmission lines, where the multiple first-type transmission lines are electrically connected to connection points on the multiple signal lines, and the multiple first-type transmission lines are configured to transmit a display signal, and where at least one of the multiple signal lines includes at least two of the connection points.

Based on the same inventive concept, a display device is further provided in the present disclosure, and the display device includes the above display panel, where the display panel includes:
multiple signal lines, where the multiple signal lines extend along a first direction and are arranged along a second direction; and
multiple first-type transmission lines, where the multiple first-type transmission lines are electrically connected to connection points on the multiple signal lines, and the multiple first-type transmission lines are configured to transmit a display signal, and where at least one of the multiple signal lines includes at least two of the connection points.

### BRIEF DESCRIPTION OF THE DRAWINGS

To more clearly illustrate the embodiments of the present disclosure or the conventional technology, the following briefly introduces the drawings required to be used in the description of the embodiments or the conventional technology.

FIG. 1 is a schematic diagram of part of lines of a display panel provided according to an embodiment of the present disclosure;

FIG. 2 is a schematic diagram of part of lines of a display panel provided according to another embodiment of the present disclosure;

FIG. 3 is a schematic diagram of part of lines of a display panel provided according to another embodiment of the present disclosure;

FIG. 4 is a schematic diagram of part of lines of a display panel provided according to another embodiment of the present disclosure;

FIG. 5 is a schematic diagram of part of lines of a display panel provided according to another embodiment of the present disclosure;

FIG. 6 is a schematic diagram of part of lines of a display panel provided according to another embodiment of the present disclosure;

FIG. 7 is a schematic diagram of a partial layout at a pixel Pi provided according to an embodiment of the present disclosure;

FIG. 8 is a schematic diagram of part of lines of a display panel provided according to another embodiment of the present disclosure;

FIG. 9 is a schematic diagram of part of lines of a display panel provided according to another embodiment of the present disclosure;

FIG. 10 is a schematic diagram of part of lines of a display panel provided according to another embodiment of the present disclosure;

FIG. 11 is a schematic diagram of a signal line provided according to an embodiment of the present disclosure;

FIG. 12 is a schematic diagram of a signal line provided according to another embodiment of the present disclosure;

FIG. 13 is a schematic diagram of part of lines of a display panel provided according to another embodiment of the present disclosure;

FIG. 14 is a partial view showing a stacked structure of a display panel provided according to an embodiment of the present disclosure;

FIG. 15 is a partial view showing a stacked structure of a display panel provided according to another embodiment of the present disclosure;

FIG. 16 is a schematic diagram of a partial layout at a pixel Pi provided according to another embodiment of the present disclosure;

FIG. 17 is a schematic diagram of part of lines of a first-type transmission line provided according to an embodiment of the present disclosure;

FIG. 18 is a schematic diagram of part of lines of a second-type transmission line provided according to an embodiment of the present disclosure;

FIG. 19 is a partial view showing a stacked structure of a display panel provided according to another embodiment of the present disclosure;

FIG. 20 is a partial view showing a stacked structure of a display panel provided according to another embodiment of the present disclosure;

FIG. 21 is a partial view showing a stacked structure of a display panel provided according to another embodiment of the present disclosure; and

FIG. 22 is a structural schematic diagram of a display device provided according to an embodiment of the present disclosure.

### REFERENCE NUMERALS

10: display panel; 101: substrate; 102: gate metal layer; 103: source-drain metal layer;
104: gate insulating layer; 105: semiconductor layer; 106: interlayer insulating layer;
107: passivation layer; 108: light-shielding metal layer; 109: wiring metal layer;
110: signal line; 1101: first line segment; 1102: second line segment; 111: connection point;
121: first-type transmission line; 122: second-type transmission line; 1211: input line;
1212: connection line; 1213: transition line; 12131: first transition line;
12132: second transition line; 130: display control circuit; 141: first transmission extension line;
142: second transmission extension line; 1000: display device.

### DETAILED DESCRIPTION

The following clearly and completely describes the embodiments of the present disclosure in conjunction with the drawings in the embodiments of the present disclosure. Apparently, the described embodiments are only a part of the embodiments of the present disclosure, rather than all of the embodiments.

As described in the Background, with the development of display technology, the requirements for display quality have gradually increased. Currently, narrow bezel or even bezel-less design is a development trend in the conventional display technology field. To achieve a narrow bezel or bezel-less design for a display device, related wiring lines are generally arranged within an active area of the display device, where the wiring lines include multiple signal lines and multiple transmission lines, one signal line is electrically connected to multiple pixels, and one signal line is electrically connected to one transmission line. The transmission line is configured to transmit a display signal to the signal line, and then the display signal is transmitted to the multiple pixels electrically connected to the signal line via the signal line. Since multiple pixels are electrically connected to the signal line at different positions, delays for different pixels receiving the display signal are inconsistent, thereby affecting a display effect of the display device.

Since the multiple pixels electrically connected to the signal line are generally arranged in sequence along the extension direction of the signal line, the multiple pixels are electrically connected to the signal line at inconsistent positions, resulting in a small signal delay for a pixel close to a connection point between the signal line and the transmission line when the pixel receives the display signal, and a large signal delay for a pixel far from the connection point between the signal line and the transmission line when the pixel receives the display signal. In particular, different signal lines are located at different positions in the active area. For a pixel far from a signal line for transmitting the display signal output from a display control circuit and far from the connection point between the signal line and the transmission line, the signal delay for receiving the display signal is even larger, ultimately affecting the display effect of the display device.

Based on this, a display panel and a display device are provided according to embodiments of the present disclosure, to effectively address the technical issues in the conventional technology, reduce the impedance on the transmission path of the display signal, improve the transmission efficiency of the transmission path of the display signal, thereby addressing the issue of large difference in signal delay at different positions on the signal line, and improving the display effect of the display device.

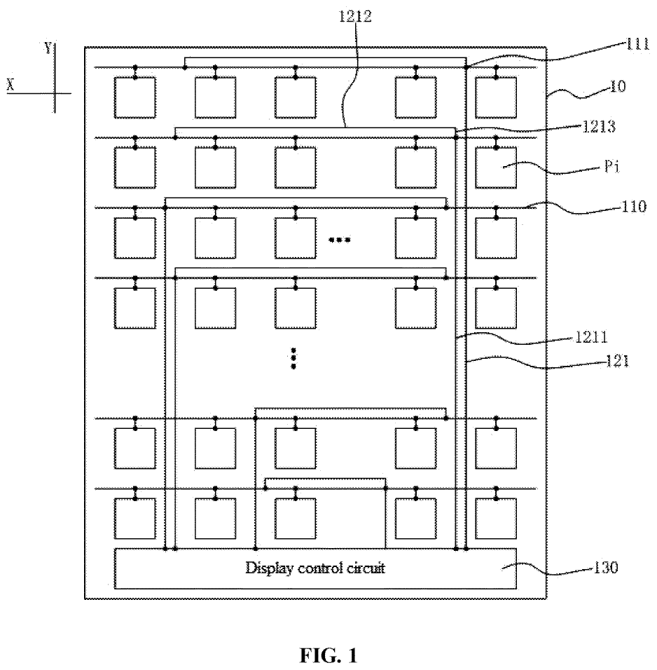

To achieve the above object, the embodiments provided by the embodiments of the present disclosure are as follows, and the embodiments provided by the embodiments of the present disclosure are described in detail in conjunction with FIG. 1 to FIG. 22.

Referring to FIG. 1, FIG. 1 is a schematic diagram of part of lines of a display panel provided according to an embodiment of the present disclosure. The display panel 10 provided by the embodiment of the present disclosure includes multiple signal lines 110 and multiple first-type transmission lines 121. Each signal line 110 is electrically connected to multiple pixels Pi for transmitting a display signal to the corresponding pixels Pi to drive the pixels Pi to display an image. The signal lines 110 extend along a first direction X and are arranged along a second direction Y, where the first direction X intersects with the second direction Y (e.g., the first direction X and the second direction Y are arranged perpendicular to each other). The multiple first-type transmission lines 121 are electrically connected to connection points 111 on the signal lines 110, respectively. For example, a first-type transmission line 121 is electrically connected to a connection point 111 on a signal line 110 corresponding to the first-type transmission line 121. The first-type transmission lines 121 are configured to transmit a display signal. At least one of the signal lines 110 includes at least two of the connection points 111. The display panel 10 further includes a display control circuit 130. The display control circuit 130 may be arranged on a same side of all the signal lines 110 in the second direction Y. The display control circuit 130 is electrically connected to the first-type transmission lines 121 for outputting the display signal to the first-type transmission lines 121.

In some embodiments, the first-type transmission lines 121 and the signal lines 110 provided by the embodiments of the present disclosure may be located in a gap area formed by pixels Pi. That is, the display panel 10 provided by the embodiments of the present disclosure includes multiple pixels Pi arranged in an array. The multiple pixels Pi form multiple pixel columns arranged along the first direction X and multiple pixel rows arranged along the second direction Y. At least part of line segments of the signal line 110 are arranged between adjacent pixel rows, and at least part of line segments of the first-type transmission line 121 are arranged between adjacent pixel columns, thereby reducing the influence of the lines on the light transmittance of the panel.

From the above description, it can be seen that in the embodiments of the present disclosure, at least two connection points 111 are provided on the signal line 110 and the at least two connection points 111 are electrically connected to the first-type transmission line 121, increasing the signal transmission channels from the first-type transmission line 121 to the signal line 110, that is, reducing the impedance on the transmission path of the display signal, improving the transmission efficiency of the transmission path of the display signal, thereby addressing the issue of large difference in signal delay at different positions on the signal line 110, and improving the display effect of the display device. In some embodiments, the display panel 10 provided by the embodiments of the present disclosure includes an active area, where all the signal lines 110 may be located within the active area, the display control circuit 130 is located on one side of the active area in the second direction Y, and the first-type transmission lines 121 are electrically connected to the display control circuit 130. For each of the first-type transmission lines 121, the first-type transmission line 121 starts from a connection point between the first-type transmission line 121 and the display control circuit 130 and directly extends along the second direction Y into the active area to be electrically connected to the connection point 111 of the signal line 110, thereby realizing a narrow bezel or bezel-less design of the display panel 10 in the first direction X. In an embodiment, the display panel 10 provided by the embodiment of the present disclosure includes a driver IC (Integrated Circuit) located on one side of the active area in the second direction Y, and the display control circuit 130 may be integrated and arranged in the driver IC, which is not particularly limited in the present disclosure.

Continuing to refer to FIG. 1, for the signal line 110 and the first-type transmission line 121 connected to the signal line 110, the first-type transmission line 121 includes at least one input line 1211 and one connection line 1212, where one end of the input line 1211 is supplied with the display signal, and the other end of the input line 1211 is electrically connected to any of the connection points 111 on the signal line 110. The connection line 1212 is electrically connected to all the connection points 111 on the signal line 110. The input line 1211 and the connection line 1212 provided by the embodiments of the present disclosure may be arranged on two sides of the signal line 110 in the second direction Y, that is, in the second direction Y, all the pixels Pi electrically connected to the signal line 110 are located on the same side of the signal line 110. The input line 1211 and the connection line 1212 are respectively arranged on the two sides of the signal line 110, thereby facilitating the wiring of the input line 1211 and the connection line 1212. Further, the first-type transmission line 121 provided by the embodiment of the present disclosure includes a transition line 1213 located between the connection line 1212 and the signal line 110, where one end of the transition line 1213 is electrically connected to one of the connection points 111 on the signal line 110, and the other end of the transition line 1213 is electrically connected to the connection line 1212. The extension direction of the transition line 1213 is identical to the extension direction of the input line 1211, and one transition line 1213 is located on the extension path of the input line 1211. In a case that the extension direction of the transition line 1213 and the extension direction of the input line 1211 are both set along the second direction Y, the transition line 1213 connected to the same connection point 111 as the input line 1211 is located on the extension path of the input line 1211, thereby ensuring high uniformity of the morphology of the first-type transmission line 121 in the second direction Y, improving the quality of the lines subsequently prepared for the display panel 10, reducing the risk of line breakage in the subsequently prepared lines of the display panel 10, and improving the reliability and manufacturing yield of the display panel 10.

In the direction perpendicular to the plane where the display panel 10 is located, the display panel 10 is formed by multiple stacking layers. Both the extension direction of the transition line 1213 and the extension direction of the input line 1211 are set to be the same. For example, both the extension direction of the transition line 1213 and the extension direction of the input line 1211 are set to be along the second direction Y, causing the flatness of a part (i.e., the part including the input line 1211 and the transition line 1213 directly connected to the input line 1211 on the extension path of the input line 1211) of the first-type transmission line 121 extending in the second direction Y to be substantially uniform in the direction perpendicular to the plane where the display panel 10 is located, avoiding the transition line 1213 extending to other directions and having a gap with the input line 1211, which may cause a rough gap area between the transition line 1213 and the input line 1211 in the direction perpendicular to the plane where the display panel 10 is located. That is, the problem of poor uniformity of the morphology of the first-type transmission line 121 in the second direction Y is addressed, and the influence on subsequently prepared lines of the display panel 10 is reduced. With the embodiments provided by the embodiments of the present disclosure, the morphology uniformity of the first-type transmission line 121 in the second direction Y is high, which improves the quality of the lines subsequently prepared for the display panel 10, reduces the risk of line breakage in the subsequently prepared lines of the display panel 10, and improves the reliability and manufacturing yield of the display panel 10.

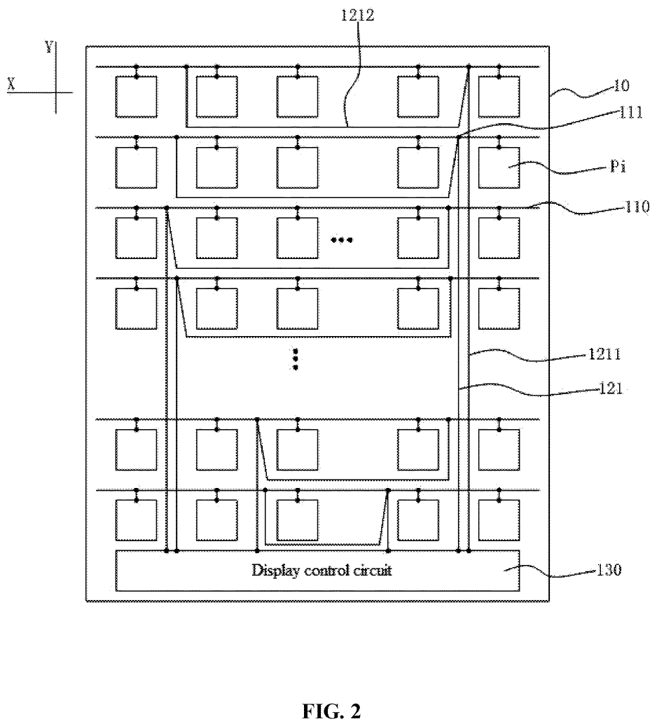

In addition, in some other embodiments of the present disclosure, the input line 1211 and the connection line 1212 provided by the embodiment of the present disclosure may be located on the same side of the signal line 110 in the second direction Y. In one embodiment, as shown in FIG. 2, FIG. 2 is a schematic diagram of part of lines of a display panel provided according to another embodiment of the present disclosure. For each of the signal lines 110 and the first-type transmission line 121 connected to the signal line 110, the input line 1211 and the connection line 1212 may be located on the same side of the signal line 110 in the second direction Y. In an embodiment, for a signal line 110 and the pixels Pi connected to the signal line 110, the pixels Pi may be located on a side of the signal line 110 facing the display control circuit 130. For the signal line 110 and the first-type transmission line 121 connected to the signal line 110, the input line 1211 and the connection line 1212 may both be located on the side of the signal line 110 facing the display control circuit 130, and the connection line 1212 may be located on a side of the pixels Pi facing away from the signal line 110, which is not particularly limited in the present disclosure and should be, in one embodiment, designed according to practical applications.

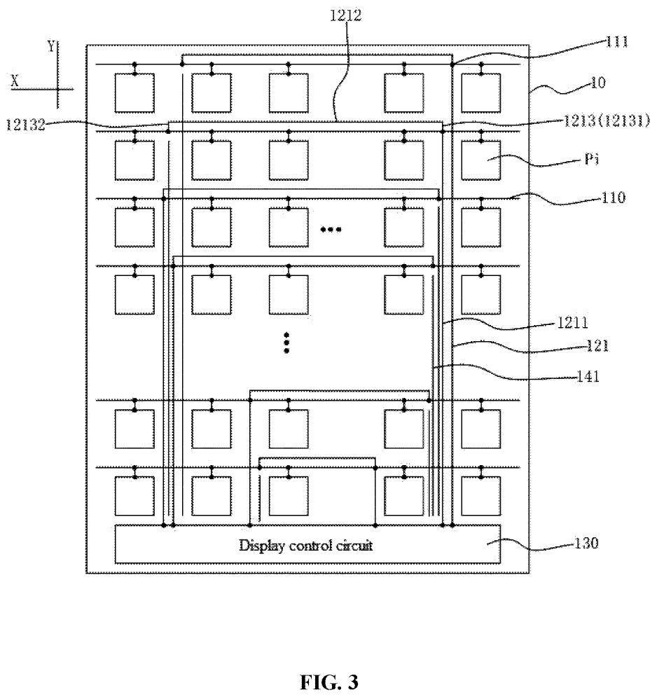

Referring to FIG. 3, FIG. 3 is a schematic diagram of part of lines of a display panel provided according to another embodiment of the present disclosure. The display panel 10 provided by the embodiment of the present disclosure further includes multiple first transmission extension lines 141. For a signal line 110 and a first-type transmission line 121 electrically connected to the signal line 110, a first transmission extension line 141 of the multiple first transmission extension lines 141 is provided at a connection point 111 of the connection points on the signal line 110, where the connection point 111 is not electrically connected to the input line 1211. The extension direction of the first transmission extension line 141 is identical to the extension direction of the input line 1211, and the first transmission extension line 141 is located on the same side of the signal line 110 as the input line 1211. The length of the first transmission extension line 141 is determined for corresponding to the signal line 110, and is substantially consistent with the length of the input line 1211 electrically connected to the signal line 110, thereby ensuring high overall line morphology uniformity of the display panel 10, further improving the quality of the lines subsequently prepared for the display panel 10, and improving the reliability and manufacturing yield of the display panel 10. For example, as shown in FIG. 3, the first-type transmission line 121 includes two transition lines 1213: a first transition line 12131 and a second transition line 12132, where the first transition line 12131 and the input line 1211 are electrically connected to the same connection point 111 of the signal line 110, and the second transition line 12132 is electrically connected to the connection line 1212 and another connection point 111 of the signal line 110, and the another connection point 111 corresponds to the first transmission extension line 141. The extension directions of the first transition line 12131, the second transition line 12132, the input line 1211, and the first transmission extension line 141 all extend along the second direction Y. The extension length of the first transmission extension line 141 is similar to the extension length of the input line 1211, and the morphology of the structure formed by the first transition line 12131 and the input line 1211 is substantially consistent with the morphology of the structure formed by the second transition line 12132 and the first transmission extension line 141, thereby improving the overall line morphology uniformity of the display panel 10.

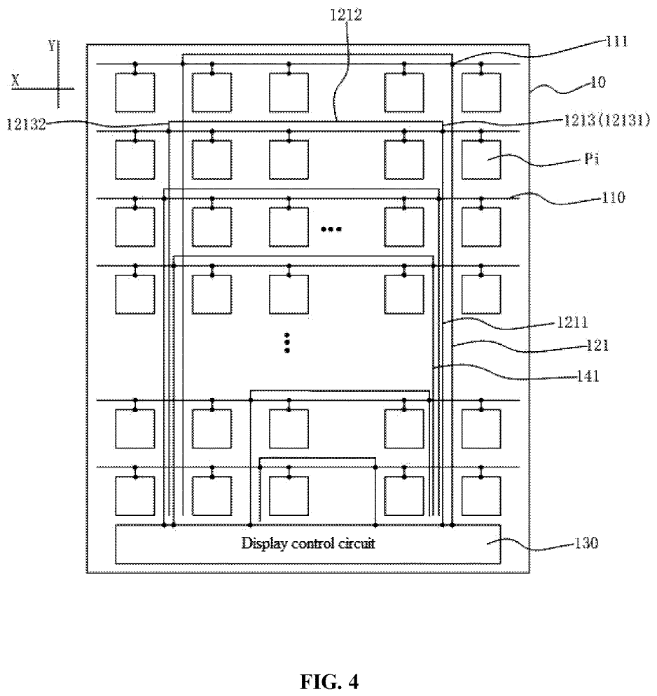

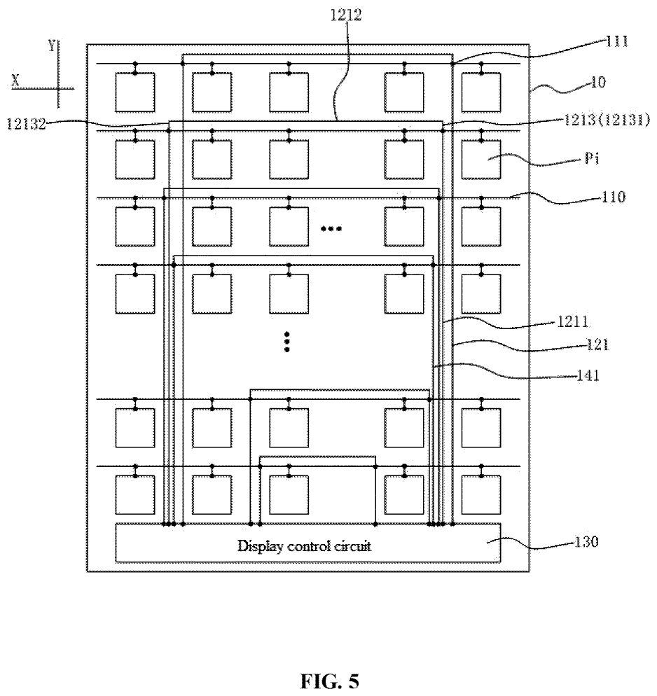

In some embodiments, the first transmission extension line 141 provided by the embodiments of the present disclosure is not electrically connected to the corresponding connection point 111, and is not electrically connected to an output port of the display signal. That is, an isolation gap is provided between the first transmission extension line 141 and the connection point 111, and an isolation gap is provided between the first transmission extension line 141 and the display control circuit 130, thereby avoiding the situation where a short circuit between the first transmission extension line 141 and other lines causes the signal line 110 and the display control circuit 130 to be short-circuited with other lines to result in problems in the panel lines. Therefore, the reliability of the display panel 10 is improved. In an embodiment, as shown in FIG. 4, the first transmission extension line 141 provided by the embodiment of the present disclosure is electrically connected to the corresponding connection point 111, and is not electrically connected to the output port of the display signal. That is, the first transmission extension line 141 is electrically connected to the connection point 111, and an isolation gap is provided between the first transmission extension line 141 and the display control circuit 130. In an embodiment as shown in FIG. 5, the first transmission extension line 141 provided by the embodiment of the present disclosure is electrically connected to the corresponding connection point 111, and is electrically connected to the output port of the display signal. That is, the first transmission extension line 141 is electrically connected to the connection point 111, and is electrically connected to the display control circuit 130. Thereby, while ensuring high overall line morphology uniformity of the display panel 10, the display signal is transmitted to the signal line 110 simultaneously through the first transmission extension line 141 and the first-type transmission line 121, further reducing the difference in signal delay of the display signal transmitted to the respective pixels Pi connected to the signal line 110, and improving the display effect of the display device.

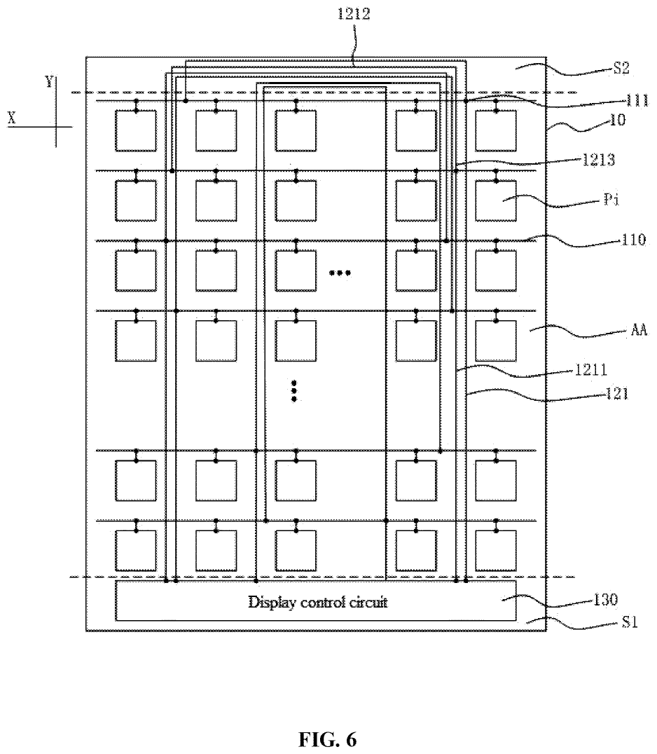

In some embodiments, the display panel 10 provided by the embodiments of the present disclosure includes an active area AA, and a bezel area located on a side of the active area AA in the second direction Y. When the first-type transmission line 121 includes a connection line 1212, the connection line 1212 may be located in the bezel area. As shown in FIG. 6, FIG. 6 is a schematic diagram of part of lines of a display panel provided according to another embodiment of the present disclosure. The connection line 1212 is located outside the active area AA of the display panel 10, thereby avoiding the connection line 1212 from affecting the wiring space of the active area AA. In an embodiment, the display panel 10 provided by the embodiment of the present disclosure includes an active area AA, and a lower bezel area S1 and an upper bezel area S2 located on two sides of the active area AA in the second direction Y. The display control circuit 130 may be arranged in the lower bezel area S1, and fewer lines may be arranged in the upper bezel area S2. In the first direction X, the display panel 10 may include a narrow bezel located on at least one side of the active area AA, or a bezel-less design on both sides of the active area AA, which is not particularly limited in the present disclosure. When the first-type transmission line 121 includes a connection line 1212, the connection line 1212 may be arranged within the upper bezel area S2, thereby avoiding the connection line 1212 from affecting the wiring space and aperture ratio at the active area AA. For example, when the display panel 10 is a display panel of electronic paper, since electronic paper does not have a critical need for a high aperture ratio, the arrangement of the connection line 1212 in the upper bezel area S2 prevents the connection line 1212 from affecting the wiring at the active area AA of the electronic paper, and further prevents affecting the light transmittance at the active area AA.

In an embodiment, the connection line 1212 provided by the embodiment of the present disclosure may be located between adjacent signal lines 110, thereby avoiding the situation where the arrangement of the connection line 1212 within the bezel area affects the narrow bezel design. As shown in FIG. 1 to FIG. 5, in the display panel 10 provided by the embodiment of the present disclosure, at least one connection line 1212 is provided between at least one pair of adjacent two signal lines 110. In one embodiment, referring to FIG. 7, FIG. 7 is a schematic diagram of a partial layout at a pixel Pi provided according to an embodiment of the present disclosure. The connection line 1212 provided by the embodiment of the present disclosure may be located between adjacent signal lines 110, that is, the connection line 1212 is located between adjacent pixel rows in the active area (e.g., on one side of the pixel Pi in FIG. 7), thereby reducing a connection distance between the input line 1211 and the connection line 1212, reducing the overall impedance of the first-type transmission line 121, and further avoiding the situation where the arrangement of the connection line 1212 in the bezel area affects the narrow bezel design. The extension direction of the connection line 1212 provided by the embodiment of the present disclosure is consistent with the extension direction of the signal line 110. In this case, the connection line 1212 may be located at the same conductive film layer as the signal line 110; or, the conductive film layer where the connection line 1212 is located may be different from the conductive film layer where the signal line 110 is located. When the conductive film layer where the connection line 1212 is located is different from the conductive film layer where the signal line 110 is located, an original film layer of the display panel 10 may be reused as the conductive film layer where the connection line 1212 is located, or the conductive film layer where the connection line 1212 is located may be prepared independently based on the original film layer of the display panel 10, which is not particularly limited in the present disclosure.

When the display panel 10 provided by the embodiments of the present disclosure is a panel of electronic paper, the pixel Pi may include structures such as a pixel electrode; or, when the display panel 10 is a panel of other types of devices, the structure included in the pixel Pi is identical to the structure included in a pixel of an existing device, which is identical to the conventional technology, so it is not elaborated in the present disclosure.

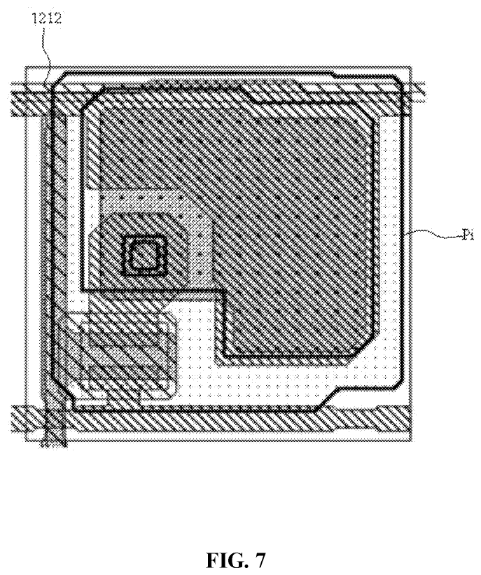

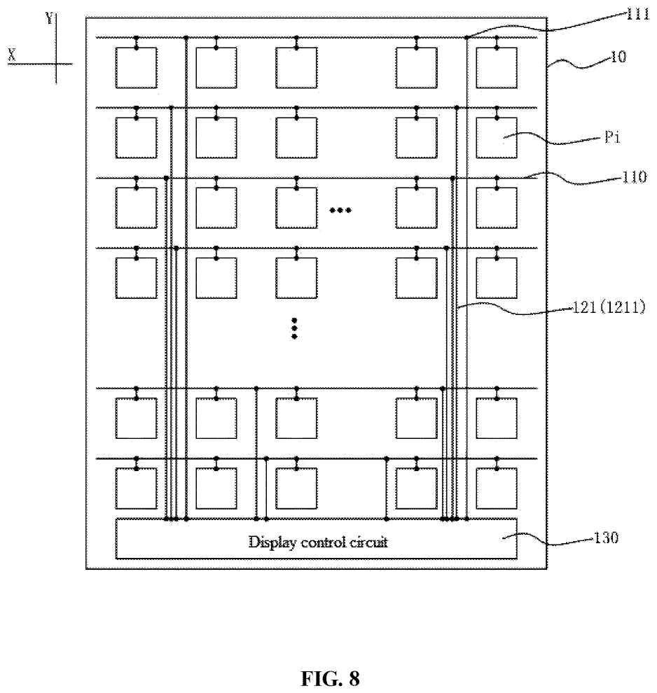

In the above embodiments, the first-type transmission line 121 is electrically connected to the connection points 111 on the signal line 110 through the connection line 1212, thereby achieving the purpose of increasing the signal transmission channels from the first-type transmission line 121 to the signal line 110. In some other embodiments of the present disclosure, the number of input lines 1211 may be increased. By connecting the respective input lines 1211 to all the connection points 111 on the signal line 110, the purpose of increasing the signal transmission channels from the first-type transmission line 121 to the signal line 110 is achieved. In one embodiment, referring to FIG. 8, FIG. 8 is a schematic diagram of part of lines of a display panel provided according to another embodiment of the present disclosure. The first-type transmission line 121 includes at least two input lines 1211, and the number of input lines 1211 is identical to the number of connection points 111 on the signal line 110 electrically connected to the first-type transmission line 121. One end of each input line 1211 is supplied with the display signal, and the other end of the input line 1211 is electrically connected to one connection point 111 on the signal line 110. The input lines 1211 are electrically connected to different connection points 111. It can be seen that through electrical connections between different input lines 1211 and different connection points 111, the different input lines 1211 are equivalently connected in parallel with each other, and thus the purpose of increasing the signal transmission channels from the first-type transmission line 121 to the signal line 110 is achieved, reducing the impedance on the transmission path of the display signal, improving the transmission efficiency of the transmission path of the display signal, thereby addressing the problem of large difference in signal delay at different positions on the signal line 110, and improving the display effect of the display device. In addition, through electrical connections between different input lines 1211 and different connection points 111, when a breakage occurs in one input line 1211 included in the first-type transmission line 121, transmission of the display signal for the signal line 110 can be implemented via other input lines 1211, thereby increasing the service life of the display panel 10.

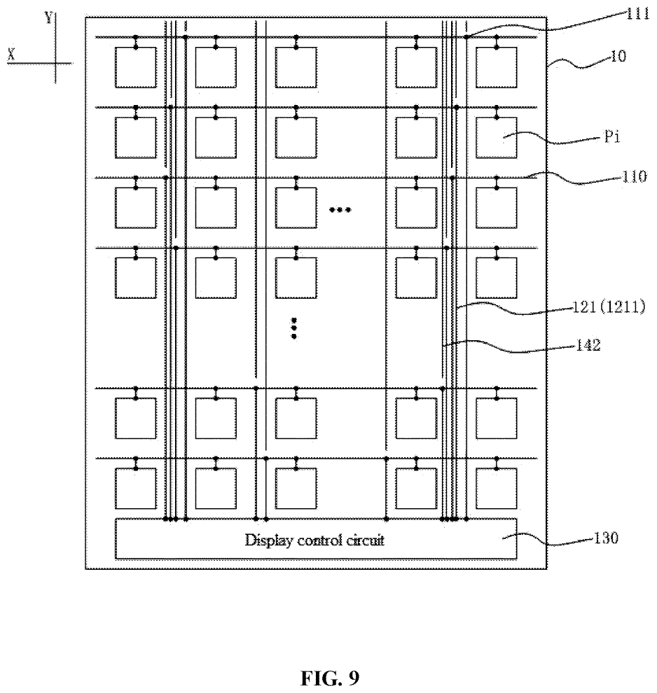

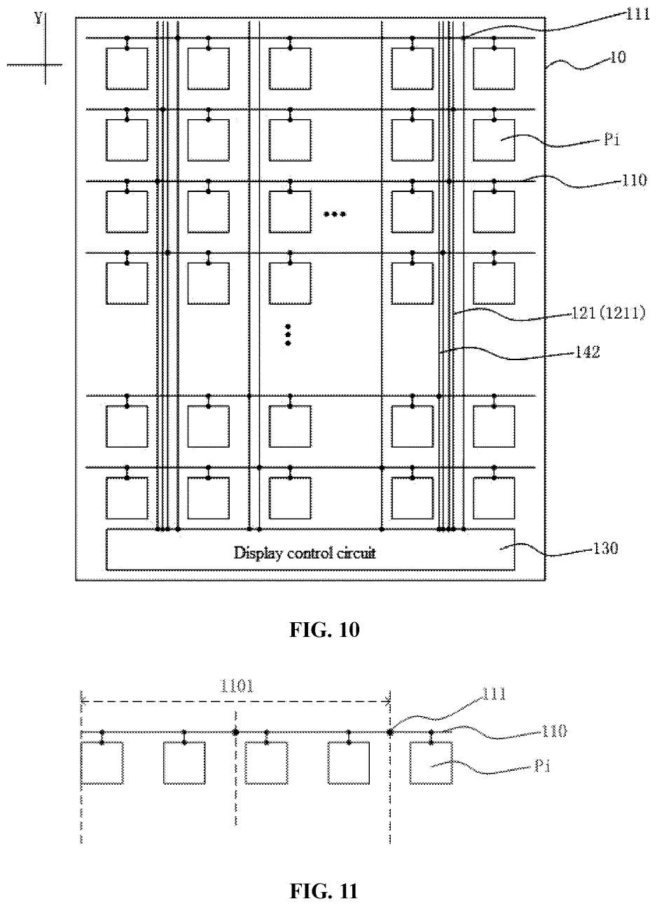

Referring to FIG. 9, FIG. 9 is a schematic diagram of part of lines of a display panel provided according to another embodiment of the present disclosure. The display panel 10 provided by the embodiment of the present disclosure further includes at least one second transmission extension line 142. For a signal line 110 and the first-type transmission line 121 electrically connected to the signal line 110, one of the at least one second transmission extension line 142 is provided at one connection point 111. In the second direction Y, the second transmission extension line 142 and the input line 1211 are located on two sides of the signal line 110, the extension direction of the second transmission extension line 142 is identical to the extension direction of the input line 1211, and the end portions of different second transmission extension lines 142 on the side facing away from the respective connection points 111 are flush with each other, thereby ensuring high uniformity of the line morphology in the display panel 10. In some embodiments, the second transmission extension line 142 provided by the embodiment of the present disclosure is not electrically connected to the connection point 111, that is, as shown in FIG. 9, an isolation gap is provided between the second transmission extension line 142 and the connection point 111, thereby avoiding faults in the lines of the display panel 10 when a short circuit occurs between the second transmission extension line 142 and other lines, and improving the reliability of the display panel 10. As shown in FIG. 10, FIG. 10 is a schematic diagram of part of lines of a display panel provided according to another embodiment of the present disclosure, the second transmission extension line 142 provided by the embodiment of the present disclosure is electrically connected to the connection point 111, which is not particularly limited in the present disclosure and should be, in one embodiment, designed according to practical applications.

In the embodiments of the present disclosure, the implementation in which the first-type transmission line 121 is electrically connected to all the connection points 111 on the signal line 110 includes, but is not limited to, the first-type transmission line 121 being electrically connected to all the connection points 111 on the signal line 110 through the connection line 1212, and further includes, but is not limited to, the first-type transmission line 121 being electrically connected to all the connection points 111 on the signal line 110 through different input lines 1211. In other embodiments of the present disclosure, the first-type transmission line 121 may further be electrically connected to all the connection points 111 on the signal line 110 through other implementations, which should be, in one embodiment, designed according to practical applications. The number of connection points 111 on the signal line 110 determines the number of transmission channels for the display signal. In an embodiment, in the second direction Y, the display panel 10 includes multiple display signal terminals located on the same side of the multiple signal lines 110, where the display signal terminals are output ports of the display control circuit 130, and the display signal terminals are configured to output the display signal. The number of the connection points 111 on the signal line 110 is positively correlated with the distance from the signal line 110 to the display signal terminals. That is, a larger distance from the signal line 110 to the display control circuit 130 indicates a greater number of connection points 111 on the signal line 110. Conversely, a smaller distance from the signal line 110 to the display control circuit 130 indicates a smaller number of connection points 111 on the signal line 110. In other words, in the second direction Y, the number of connection points 111 on the signal line 110 decreases in the direction pointing from the signal line 110 to the display control circuit 130. Therefore, it is achieved that the number of the transmission channels for the display signal of the far-end signal line 110 (i.e., the signal line 110 far from the display control circuit 130) is greater than the transmission channels for the display signal of the near-end signal line 110 (i.e., the signal line 110 close to the display control circuit 130), which is equivalent to reducing the display signal transmission impedance of the far-end signal lines 110, reducing the difference in display signal transmission between the far-end signal line 110 and the near-end signal line 110, and thus improving the display effect of the display panel 10.

In some embodiments of the present disclosure, the signal lines 110 of the display panel 10 may be divided into multiple signal line groups along the direction pointing from the signal lines 110 to the display control circuit 130, each signal line group may include the same number or different numbers of signal lines 110. The number of connection points 111 on the signal lines 110 in the same signal line group is the same, and the number of connection points 111 on the signal lines 110 in the signal line group is positively correlated with the distance from the signal line group to the display control circuit 130. That is, the number of connection points 111 on the signal line 110 in the signal line group far from the display control circuit 130 is greater than the number of connection points 111 of the signal line 110 in the signal line group close to the display control circuit 130. The manner of dividing the signal lines 110 into groups can address the problem of increased wiring difficulty caused by the number of connection points 111 on all signal lines 110 being different from each other. On the basis of reducing the difference in display signal transmission between the far-end signal line 110 and the near-end signal line 110, the wiring difficulty of the display panel 10 is reduced.

In some embodiments, the signal line 110 provided by the embodiments of the present disclosure may be equally divided by the connection points 111, thereby reducing the difference in delay of the display signal transmitted from the signal line 110 to different pixels Pi. In an embodiment, to avoid the problem of wiring overlap of some input lines 1211 of different first-type transmission lines 121, the connection points 111 provided by the embodiments of the present disclosure may equally divide some line segments in the signal line 110, to minimize the difference in delay of the display signal transmitted from the signal line 110 to different pixels Pi, and improve the display effect of the display panel 10. As shown in FIG. 11, FIG. 11 is a schematic diagram of a signal line provided according to an embodiment of the present disclosure. The signal line 110 includes a first line segment 1101, one end portion of the first line segment 1101 is one end portion of the signal line 110, the other end portion of the first line segment 1101 is one of the connection points 111, and another connection point of the connection points 111 is located between the two end portions of the first line segment 1101. The first line segment 1101 is equally divided by the connection point 111. Thus, on the basis of addressing the problem of large difference in signal delay when the signal line 110 transmits the display signal to different pixels Pi by increasing the transmission channels of the display signal, the first line segment 1101 is equally divided by the connection point 111, the difference in signal delay when the display signal is transmitted to different pixels Pi is further reduced, and the display effect of the display panel 10 is improved.

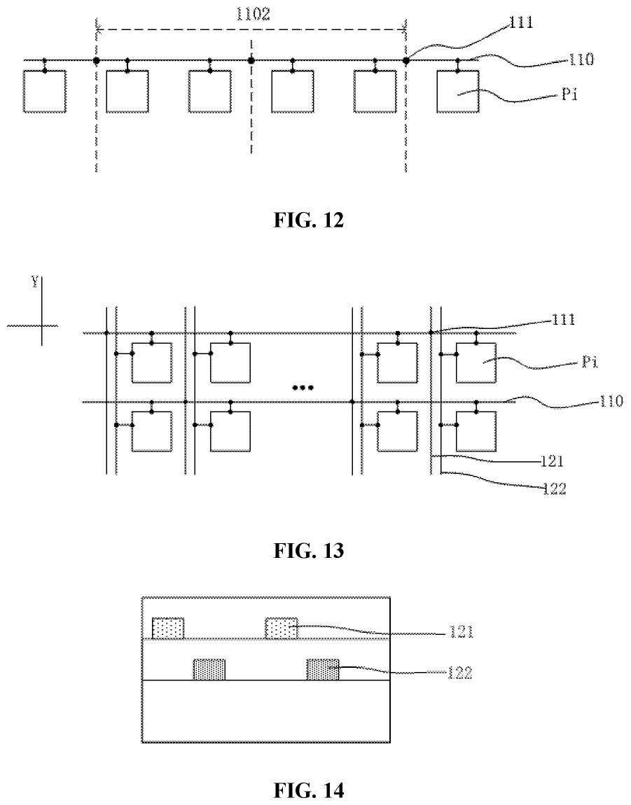

FIG. 11 illustrates a schematic diagram where the connection point 111 equally divides the first line segment 1101 at the end portion of the signal line 110. In some embodiments, the connection point 111 on a signal line 110 may further equally divide a line segment in the middle portion of the signal line 110. Referring to FIG. 12, FIG. 12 is a schematic diagram of a signal line provided according to another embodiment of the present disclosure. The signal line 110 includes a second line segment 1102, the second line segment 1102 includes three consecutive connection points 111. Two end portions of the second line segment 1102 are two connection points 111 respectively located at two sides among the three consecutive connection points 111, and the connection point 111 located in the middle equally divides the second line segment 1102. Thus, on the basis of addressing the problem of large difference in signal delay when the signal line 110 transmits the display signal to different pixels Pi by increasing the transmission channels of the display signal, the second line segment 1102 is equally divided by the connection points 111, the difference in signal delay when the display signal is transmitted to different pixels Pi is further reduced, and the display effect of the display panel 10 is improved.

In conjunction with FIG. 13 and FIG. 14, FIG. 13 is a schematic diagram of part of lines of a display panel provided according to another embodiment of the present disclosure, and FIG. 14 is a partial view showing a stacked structure of a display panel provided according to an embodiment of the present disclosure. The display panel 10 further includes multiple second-type transmission lines 122 arranged along the first direction X, and the second-type transmission lines 122 extend along the second direction Y. At least part of line segments of the first-type transmission lines 121 are arranged in a layer different from at least part of line segments of the second-type transmission lines 122, thereby increasing the wiring area in a direction parallel to the plane of the display panel 10, and also reducing line coupling in the direction parallel to the plane of the display panel 10. In an embodiment, the entirety of the first-type transmission lines 121 is arranged in a layer different from that of the entirety of the second-type transmission lines 122 provided by the embodiment of the present disclosure; or, part of the line segments of the first-type transmission lines 121 are arranged in a layer different from that of the entirety of the second-type transmission lines 122. For example, the input lines 1211 of the first-type transmission lines 121 are arranged in a layer different from that of the second-type transmission lines 122; or, the entirety of the first-type transmission lines 121 is arranged in a layer different from that of part of the line segments of the second-type transmission line 122, which is not particularly limited in the present disclosure. In some embodiments, the entirety of the first-type transmission lines 121 provided by the embodiment of the present disclosure may be located in the same conductive film layer. In one embodiment, at least part of the line segments of the first-type transmission lines 121 may be located in a conductive film layer different from that of remaining line segments of the first-type transmission lines. For example, the input lines 1211 and the transition lines 1213 may be located in the same conductive film layer different from a conductive film layer where the connection lines 1212 are located; or, the transition lines 1213 and the connection lines 1212 are located in the same conductive film layer different from a conductive film layer where the input lines 1211 are located; or, the input lines 1211, the connection lines 1212, and the transition lines 1213 are located in respective conductive film layers different from each other, which is not particularly limited in the present disclosure and should be, in one embodiment, designed according to actual requirements.

In the lines of the display panel 10, the second-type transmission line 122 directly electrically connected to the pixels Pi is included. In addition to transmitting the display signal to the signal line 110 through the first-type transmission line 121 and transmitting the display signal to the pixels Pi through the signal line 110, a function signal is transmitted to the pixels Pi through the second-type transmission line 122. The function signal cooperates with the display signal transmitted by the first-type transmission line 121 to control the pixels Pi to display an image. The second-type transmission line 122 may also be electrically connected to the display control circuit 130 and be supplied with the function signal by the display control circuit 130. In an embodiment of the present disclosure, the signal line 110 may be a gate line or a data line. That is, the signal line 110 provided by the embodiment of the present disclosure may be a gate line, the display signal transmitted through the first-type transmission line 121 is a scan control signal, the second-type transmission line 122 is a data line, and the function signal transmitted through the second-type transmission line 122 is a data signal; or, the signal line 110 may be a data line, the display signal transmitted through the first-type transmission line 121 is a data signal, the second-type transmission line 122 is a gate line, and the function signal transmitted by the second-type transmission line 122 is a scan control signal.

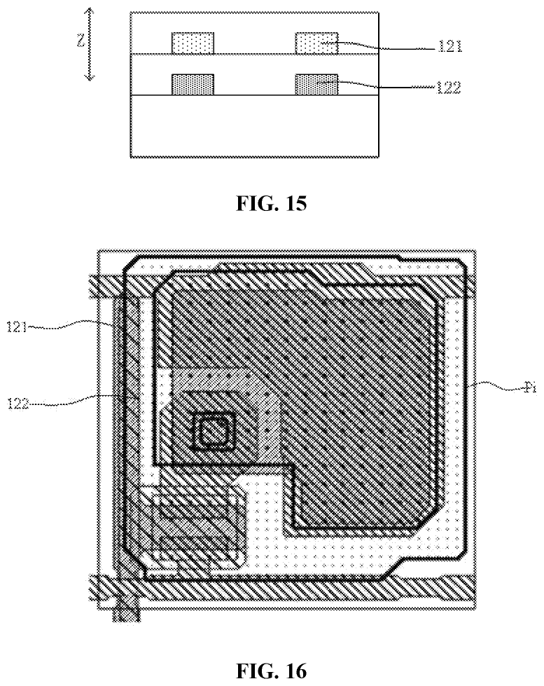

In some embodiments, when at least part of the line segments of the first-type transmission lines 121 are arranged in a layer different from that of at least part of the line segments of the second-type transmission lines 122, at the line segments arranged in different layers, the first-type transmission line 121 may be located above the second-type transmission line 122 in the stacking direction, or the first-type transmission line 121 may be located below the second-type transmission line 122 in the stacking direction, which is not particularly limited in the present disclosure. As shown in FIG. 15, FIG. 15 is a partial view showing a stacked structure of a display panel provided according to another embodiment of the present disclosure. At each of the line segments of the first-type transmission lines 121 and the second-type transmission lines 122 that are arranged in different layers, the first-type transmission line 121 and the second-type transmission line 122 overlap with each other in a direction Z perpendicular to the display panel 10 and form an overlapping area, thereby further increasing the wiring area in the direction parallel to the plane of the display panel 10. In one embodiment, in conjunction with FIG. 16, FIG. 16 is a schematic diagram of a partial layout at a pixel Pi provided according to another embodiment of the present disclosure. The first-type transmission line 121 is a gate line, and the second-type transmission line 122 is a data line; or, the first-type transmission line 121 is a data line, and the second-type transmission line 122 is a gate line. When at least part of the line segments of the first-type transmission line 121 and the second-type transmission line 122 are arranged in different layers, at the line segments of the first-type transmission line 121 and the second-type transmission line 122 that are arranged in different layers, the first-type transmission line 121 and the second-type transmission line 122 overlap with each other in the direction Z perpendicular to the display panel 10 and form an overlapping area, thereby increasing the wiring area in the direction parallel to the plane of the display panel 10.

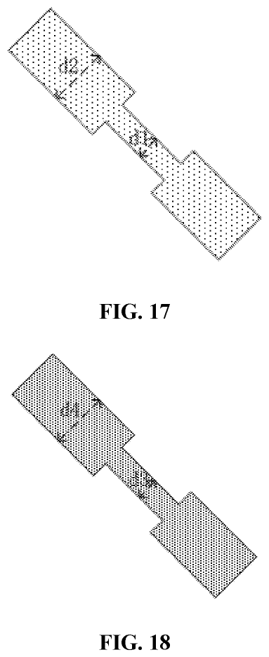

The first-type transmission line 121 and the second-type transmission line 122 form an overlapping area when viewed in the direction Z perpendicular to the display panel 10. In an embodiment of the present disclosure, the relevant structures of the first-type transmission line 121 and the second-type transmission line 122 in the overlapping area may be optimized to reduce the coupling between the first-type transmission line 121 and the second-type transmission line 122. As shown in FIG. 17, FIG. 17 is a schematic diagram of part of lines of a first-type transmission line provided according to an embodiment of the present disclosure. The line width d1 of the first-type transmission line 121 in the overlapping area is smaller than the line width d2 of the first-type transmission line 121 at remaining line segments. In one embodiment, as shown in FIG. 18, FIG. 18 is a schematic diagram of part of lines of a second-type transmission line provided according to an embodiment of the present disclosure. The line width d3 of the second-type transmission line 122 in the overlapping area is smaller than the line width d4 of the second-type transmission line 122 at remaining line segments. In an embodiment of the present disclosure, the line width d1 of the first-type transmission line 121 in the overlapping area is smaller than the line width d2 of the first-type transmission line 121 at remaining line segments, and similarly, the line width d3 of the second-type transmission line 122 in the overlapping area is smaller than the line width d4 of the second-type transmission line 122 at remaining line segments. Thereby, by reducing the line width of the transmission lines in the overlapping area, not only can the coupling problem between the first-type transmission line 121 and the second-type transmission line 122 be addressed, but also the wiring area in the direction parallel to the plane of the display panel 10 can be further increased.

In addition to reducing the line width of the transmission lines in the overlapping area, the insulation between the first-type transmission line 121 and the second-type transmission line 122 may be enhanced, that is, in the overlapping area, an insulating layer is arranged between the first-type transmission line 121 and the second-type transmission line 122, and the thickness of the insulating layer may be set to 3000 to 5000 angstroms. Furthermore, in an embodiment of the present disclosure, a display control circuit 130 with a stronger load-driving capability may be utilized, which is not particularly limited in the present disclosure and should be, in one embodiment, designed according to practical applications.

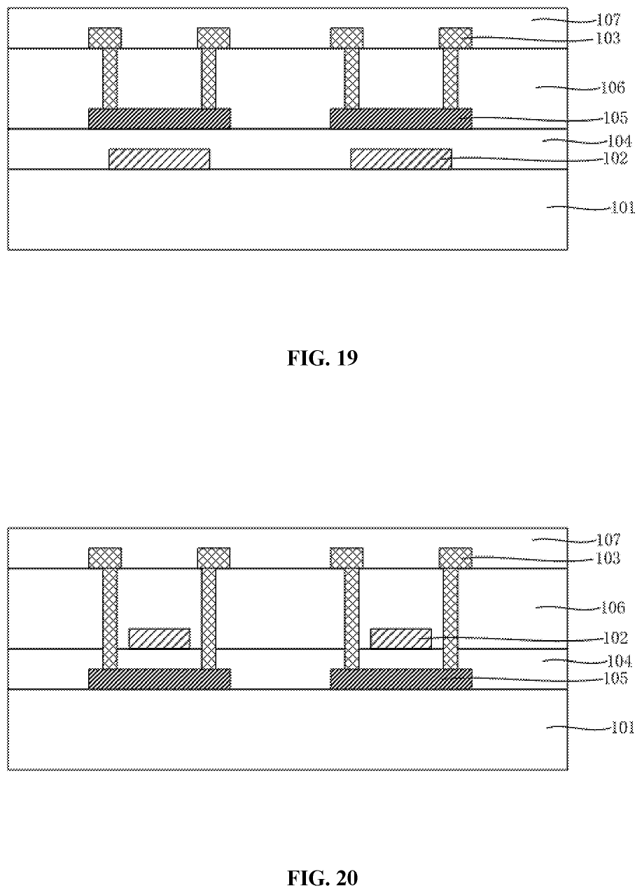

In the following, in conjunction with the view of the stacked structure of the display panel, the positions of the stacking layers where the first-type transmission line 121, the second-type transmission line 122, and the signal line 110 are located, provided by the embodiments of the present disclosure, will be described in more detail. In an embodiment, the extension directions of at least part of the line segments of the first-type transmission line 121 and at least part of the second-type transmission lines 122 are different from the extension direction of the signal line 110, therefore both the first-type transmission line 121 and the second-type transmission line 122 have crossing areas with the signal line 110. Both the first-type transmission line 121 and the second-type transmission line 122 are located in different stacking layers from the signal line 110. In the crossing areas formed by the transmission lines and the signal line 110, methods such as reducing line width and increasing the thickness of the insulating layer may be used to reduce the coupling in the crossing areas and improve the signal transmission effect of the lines. In addition, the first-type transmission line 121 and the second-type transmission line 122 may be located in the same stacking layer or at least part of the line segments of the first-type transmission line 121 and the second-type transmission line 122 may be located in different stacking layers, which is not particularly limited in the present disclosure. In one embodiment, at least part of the line segments of the first-type transmission line 121 are located at a stacking layer different from a stacking layer where the second-type transmission line 122 is located, which can effectively increase the wiring area in the direction parallel to the plane of the display panel 10. Referring to FIG. 19, FIG. 19 is a partial view showing a stacked structure of a display panel provided according to another embodiment of the present disclosure. The display panel 10 provided by the embodiment of the present disclosure includes a substrate 101, and a transistor array layer located on the substrate 101. The transistor array layer includes a gate metal layer 102 and a source-drain metal layer 103. When the at least part of the line segments of the first-type transmission lines 121 are located in one of the gate metal layer 102 and the source-drain metal layer 103, the second-type transmission lines 122 are located in the other of the gate metal layer 102 and the source-drain metal layer 103. Continuing to refer to FIG. 19, the transistor formed in the transistor array layer provided by the embodiment of the present disclosure may be a bottom-gate transistor, and the gate metal layer 102 in the display panel 10 is located on a side of the semiconductor layer 105 facing the substrate 101. The display panel 10 includes: a substrate 101; a gate metal layer 102 located on the substrate 101, where a gate of the transistor is formed in the gate metal layer 102; a gate insulating layer 104 located on a side of the gate metal layer 102 facing away from the substrate 101; a semiconductor layer 105 located on a side of the gate insulating layer 104 facing away from the substrate 101, where an active layer of the transistor is formed in the semiconductor layer 105; an interlayer insulating layer 106 located on a side of the semiconductor layer 105 facing away from the substrate 101; a source-drain metal layer 103 located on a side of the interlayer insulating layer 106 facing away from the substrate 101, where a source and a drain of the transistor are formed in the source-drain metal layer 103; and a passivation layer 107 located on a side of the source-drain metal layer 103 facing away from the substrate 101. The gate metal layer 102, the source-drain metal layer 103, the gate insulating layer 104, the semiconductor layer 105, the interlayer insulating layer 106, and the passivation layer 107 constitute the transistor array layer.

In an embodiment, as shown in FIG. 20, FIG. 20 is a partial view showing a stacked structure of a display panel provided according to another embodiment of the present disclosure. The transistor formed in the transistor array layer provided by the embodiment of the present disclosure may be a top-gate transistor, and the gate metal layer 102 in the display panel 10 is located on a side of the semiconductor layer 105 facing away from the substrate 101. The display panel 10 includes: a substrate 101; a semiconductor layer 105 located on the substrate 101, where an active layer of the transistor is formed in the semiconductor layer 105; a gate insulating layer 104 located on a side of the semiconductor layer 105 facing away from the substrate 101; a gate metal layer 102 located on a side of the gate insulating layer 104 facing away from the substrate 101, a gate of the transistor is formed in the gate metal layer 102; an interlayer insulating layer 106 located on a side of the gate metal layer 102 facing away from the substrate 101; a source-drain metal layer 103 located on a side of the interlayer insulating layer 106 facing away from the substrate 101, a source and a drain of the transistor are formed in the source-drain metal layer 103; and a passivation layer 107 located on a side of the source-drain metal layer 103 facing away from the substrate 101. The gate metal layer 102, the source-drain metal layer 103, the gate insulating layer 104, the semiconductor layer 105, the interlayer insulating layer 106, and the passivation layer 107 constitute the transistor array layer.

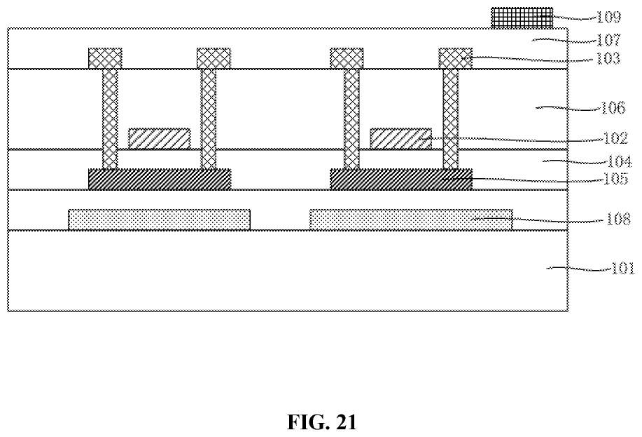

In some embodiments, the display panel 10 provided by the embodiments of the present disclosure further includes some optimized metal layers for improving the performance of the display panel 10, such as the display panel 10 further including at least one of a light-shielding metal layer 108 or a wiring metal layer 109. Referring to FIG. 21, FIG. 21 is a partial view showing a stacked structure of a display panel provided according to another embodiment of the present disclosure. FIG. 21 is based on the stacked structure of the display panel 10 including the top-gate transistor illustrated in FIG. 20. The display panel 10 further includes a light-shielding metal layer 108 located between the substrate 101 and the transistor array layer, with an insulating stacking layer arranged between the light-shielding metal layer 108 and the transistor array layer; and/or, a wiring metal layer 109 located on a side of the transistor array layer facing away from the substrate. When at least part of the line segments of the first-type transmission lines 121 may be located in one of the gate metal layer 102, the source-drain metal layer 103, the light-shielding metal layer 108, and the wiring metal layer 109, the second-type transmission lines 122 are located in one of the remaining three metal layers. By reusing the original metal layers of the display panel 10 for the first-type transmission lines 121 and the second-type transmission lines 122, eliminating the need to separately form a metal layer to prepare the transmission lines, thereby simplifying the preparation process and reducing the panel cost.

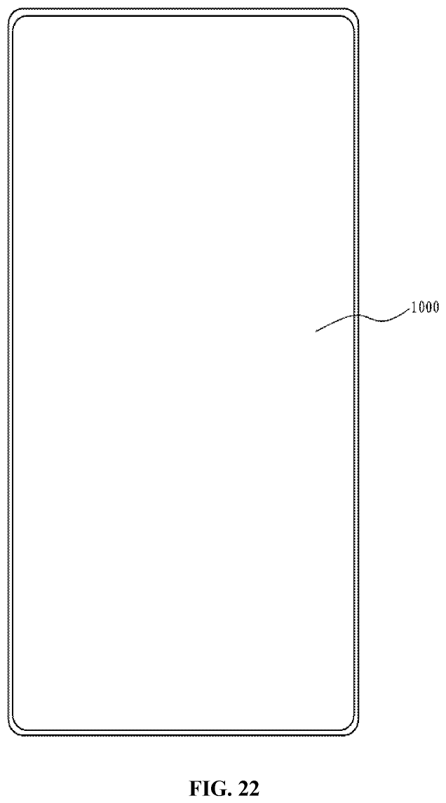

Based on the same inventive concept, a display device is further provided according to embodiments of the present disclosure. Referring to FIG. 22, FIG. 22 is a structural schematic diagram of a display device provided according to an embodiment of the present disclosure. The display device 1000 provided by the embodiment of the present disclosure includes the above display panel 10. In an embodiment, the display device 1000 provided by the embodiment of the present disclosure is electronic paper.

In some embodiments, the display device 1000 provided by the embodiments of the present disclosure may be a large or small device such as a mobile terminal, a laptop, a tablet computer, a computer, a wearable device, etc., which is not particularly limited in the present disclosure.

In summary, a display panel and a display device are provided in the embodiments of the present disclosure. The display panel includes multiple signal lines and multiple first-type transmission lines. The multiple signal lines extend along a first direction and are arranged along a second direction. The multiple first-type transmission lines are electrically connected to connection points on the multiple signal lines. The multiple first-type transmission lines are configured to transmit a display signal. At least one of the signal lines includes at least two of the connection points. It can be seen that at least two connection points are provided on the signal line and the at least two connection points are electrically connected to the first-type transmission line, increasing the signal transmission channels from the first-type transmission line to the signal line, that is, reducing the impedance on the transmission path of the display signal, improving the transmission efficiency of the transmission path of the display signal, thereby addressing the issue of large difference in signal delay at different positions on the signal line, and improving the display effect of the display device.

In the description of the embodiments of the present disclosure, terms such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, “counterclockwise”, “axial”, “radial”, “circumferential” and the like indicate orientations or positional relationships based on the orientations or positional relationships shown in the drawings, and are only for the convenience of describing the embodiments of the present disclosure and simplifying the description, rather than indicating or implying that the referred device or element must have a specific orientation, be constructed and operated in a specific orientation, and therefore cannot be understood as a limitation of the present disclosure.

In addition, terms such as “first” and “second” are used only for descriptive purposes, and cannot be understood as indicating or implying relative importance or implicitly specifying the number of the indicated technical features. Thus, features defined with “first” and “second” may explicitly or implicitly include at least one of the features. In the description of the embodiments of the present disclosure, “multiple” means at least two, such as two, three, etc., unless otherwise expressly and, in one embodiment, limited.

In the embodiments of the present disclosure, unless otherwise expressly specified and limited, terms such as “installed”, “connected”, “coupled”, “fixed” and the like should be understood in a broad sense, for example, it may be a fixed connection, a detachable connection, or an integral connection; it may be a mechanical connection, an electrical connection, or mutual communication; it may be a direct connection, or an indirect connection through an intermediate medium, it may be the internal communication between two elements or the interaction relationship between two elements, unless otherwise expressly limited. The specific meanings of the above terms in the present disclosure may be understood according to the specific circumstances.

In the embodiments of the present disclosure, unless otherwise expressly specified and limited, a first feature being “on” or “under” a second feature may indicate that the first and second features are in direct contact, or the first and second features are in indirect contact through an intermediate medium. Moreover, a first feature being “over”, “above” and “on” a second feature may indicate that the first feature is directly above or obliquely above the second feature, or simply indicates that the horizontal height of the first feature is higher than that of the second feature. A first feature being “below”, “under” and “beneath” a second feature may indicate that the first feature is directly below or obliquely below the second feature, or simply indicates that the horizontal height of the first feature is lower than that of the second feature.

In the embodiments of the present disclosure, terms such as “an embodiment”, “some embodiments”, “example”, “specific example”, or “some examples” mean that specific features, structures, materials, or characteristics described in conjunction with the embodiment or example are included in at least one embodiment or example of the present disclosure. In this specification, the schematic expressions of the above terms are not necessarily directed to the same embodiments or examples. Furthermore, the described specific features, structures, materials, or characteristics may be combined in any one or more embodiments or examples in a suitable manner. Moreover, a person can combine and integrate the different embodiments or examples and the features of the different embodiments or examples described in this specification, provided that they do not contradict each other.

Although the embodiments of the present disclosure have been shown and described above, the above embodiments are exemplary and cannot be understood as limitations of the present disclosure. A person may make changes, modifications, substitutions, and variations to the above embodiments within the scope of the present disclosure.

1. A display panel, comprising:
a plurality of signal lines, wherein the plurality of signal lines extend along a first direction and are arranged along a second direction; and
a plurality of first-type transmission lines, wherein the plurality of first-type transmission lines are electrically connected to connection points on the plurality of signal lines, and the plurality of first-type transmission lines are configured to transmit a display signal, and wherein at least one of the plurality of signal lines comprises at least two of the connection points.

2. The display panel according to claim 1, wherein for a signal line of the plurality of signal lines and the first-type transmission line electrically connected to the signal line,
the first-type transmission line comprises at least one input line and one connection line,
one end of the at least one input line is supplied with the display signal, and the other end of the at least one input line is electrically connected to any connection point on the signal line; and
the connection line is electrically connected to all the connection points on the signal line.

3. The display panel according to claim 2, wherein in the second direction, the at least one input line and the connection line are located on two sides of the signal line; and
the first-type transmission line comprises a transition line located between the connection line and the signal line, one end of the transition line is electrically connected to the connection point on the signal line, the other end of the transition line is electrically connected to the connection line, and an extension direction of the transition line is identical to an extension direction of the at least one input line.

4. The display panel according to claim 2, wherein the display panel further comprises a plurality of first transmission extension lines, and wherein
for the signal line and the first-type transmission line electrically connected to the signal line,
a first transmission extension line among the plurality of first transmission extension lines is provided at a connection point on the signal line, wherein the connection point is not electrically connected to the at least one input line, an extension direction of the first transmission extension line is identical to the extension direction of the at least one input line, and the first transmission extension line is located on a same side of the signal line as the at least one input line.

5. The display panel according to claim 4, wherein an isolation gap is provided between the first transmission extension line and the connection point.

6. The display panel according to claim 2, wherein
the connection line is located outside an active area of the display panel;
or,
at least one of the connection lines is provided between at least one pair of adjacent two signal lines of the plurality of signal lines.

7. The display panel according to claim 1, wherein a first-type transmission line of the plurality of first-type transmission lines comprises at least two input lines, for each input line of the at least two input lines, one end of the input line is supplied with the display signal, and the other end of the input line is electrically connected to a connection point on the signal line of the plurality of signal lines that is electrically connected to the first-type transmission line, and wherein
the input lines are electrically connected to different connection points on the signal line.

8. The display panel according to claim 7, wherein the display panel further comprises at least one second transmission extension line,
for the signal line and the first-type transmission line electrically connected to the signal line, one second transmission extension line of the at least one second transmission extension line is provided at one of the connection points on the signal line;
in the second direction, the second transmission extension line and the input lines are located on two sides of the signal line, and an extension direction of the second transmission extension line is identical to an extension direction of the input lines.

9. The display panel according to claim 8, wherein an isolation gap is provided between the second transmission extension line and the connection point.

10. The display panel according to claim 1, wherein in the second direction, the display panel comprises a plurality of display signal terminals located on a same side of the plurality of signal lines, and the plurality of display signal terminals are configured to output the display signal; and
among the plurality of signal lines, a quantity of the connection points on a signal line is positively correlated with a distance from the signal line to the plurality of display signal terminals.

11. The display panel according to claim 1, wherein among the plurality of signal lines,
a signal line comprises a first line segment, one end portion of the first line segment is one end portion of the signal line, the other end portion of the first line segment is one of the connection points on the signal line, and another connection point of the connection points is located between the two end portions of the first line segment, and wherein the first line segment is divided equally by the another connection point; or
a signal line comprises a second line segment, and the second line segment comprises three consecutive connection points, and wherein two end portions of the second line segment are two connection points respectively located at two sides among the three consecutive connection points, and a connection point located in the middle among the three consecutive connection points equally divides the second line segment.

12. The display panel according to claim 1, wherein the display panel further comprises a plurality of second-type transmission lines arranged along the first direction, and at least part of line segments of the plurality of first-type transmission lines are arranged in a layer different from a layer where at least part of line segments of the plurality of second-type transmission lines are arranged.

13. The display panel according to claim 12, wherein at the at least part of line segments of the plurality of first-type transmission lines and the at least part of line segments of the plurality of second-type transmission lines that are arranged in the different layers, the first-type transmission line and the second-type transmission line overlap with each other in a direction perpendicular to the display panel and form an overlapping area.

14. The display panel according to claim 13, wherein at least one of:
a line width of the first-type transmission line in the overlapping area is smaller than the line width of the first-type transmission line at remaining line segments;
or,
a line width of the second-type transmission line in the overlapping area is smaller than the line width of the second-type transmission line at remaining line segments.

15. The display panel according to claim 13, wherein in the overlapping area, an insulating layer is arranged between the first-type transmission line and the second-type transmission line, and a thickness of the insulating layer is 3000 to 5000 angstroms.

16. The display panel according to claim 12, wherein the display panel comprises:
a substrate; and
a transistor array layer, located on the substrate, wherein the transistor array layer comprises a gate metal layer and a source-drain metal layer, and wherein
when the at least part of the line segments of the plurality of first-type transmission lines are located in one of the gate metal layer and the source-drain metal layer, the plurality of second-type transmission lines are located in the other of the gate metal layer and the source-drain metal layer.

17. The display panel according to claim 16, wherein the display panel further comprises at least one of:
a light-shielding metal layer located between the substrate and the transistor array layer;
or,
a wiring metal layer located on a side of the transistor array layer facing away from the substrate,
wherein when the at least part of the line segments of the plurality of first-type transmission lines are located in one of: the gate metal layer, the source-drain metal layer, the light-shielding metal layer, and the wiring metal layer, the second-type transmission lines are located in one of remaining three metal layers.

18. The display panel according to claim 1, wherein the display panel comprises a plurality of pixels arranged in an array, and wherein the plurality of pixels form a plurality of pixel columns arranged along the first direction and form a plurality of pixel rows arranged along the second direction;
at least part of line segments of the plurality of signal lines are arranged between adjacent pixel rows of the plurality of pixel rows, and at least part of line segments of the plurality of first-type transmission lines are arranged between adjacent pixel columns of the plurality of pixel columns.

19. The display panel according to claim 1, wherein the plurality of signal lines are gate lines or data lines.

20. A display device, comprising a display panel, wherein the display panel comprises:
a plurality of signal lines, wherein the plurality of signal lines extend along a first direction and are arranged along a second direction; and
a plurality of first-type transmission lines, wherein the plurality of first-type transmission lines are electrically connected to connection points on the plurality of signal lines, and the plurality of first-type transmission lines are configured to transmit a display signal, and wherein at least one of the plurality of signal lines comprises at least two of the connection points.
